(19) United States
(12) Patent Application Publication
(10) Pub. No.: US 2005/0070049 A1
(43) Pub. Date: Mar. 31, 2005

(54) Method for fabricating wafer-level chip scale packages

(76) Inventors: S. J. Cheng, Hsinchu (TW); An-Hong Liu, Tainan City (TW); Yeong-Her Wang, Tainan City (TW); Yuan-Ping Tseng, Hsinchu (TW); Y. J. Lee, Tainan (TW)

Correspondence Address: BIRCH STEWART KOLASCH & BIRCH, PO BOX 747, FALLS CHURCH, VA, 22040-0747, US

(21) Appl. No.: 10/671,771

(22) Filed: Sep. 29, 2003

(51) Int. Cl. H01L 21/44

(52) U.S. Cl. 438/117; 438/106

(57) ABSTRACT

A method for fabricating wafer-level chip scale packages is disclosed. A plurality of sacrificial photoresists with supporting surfaces in strip or bump configuration are formed on a surface of a wafer. Then, a negative photoresist layer is covered on the sacrificial photoresists. The negative photoresist layer is patterned in order to form a plurality of dielectric supporting bars on supporting surfaces of the sacrificial photoresists. Thereafter, a plurality of metal bars are formed on the dielectric supporting bars. Then the sacrificial photoresists are removed in order to form a plurality of pin terminals of the wafer-level chip scale packages for elastically surface-mounting to substrate or printed circuit board.

### FIELD OF THE INVENTION

The present invention relates to a method for fabricating wafer-level chip scale packages and, more particularly, to a method for fabricating wafer-level chip scale packages with elastic supported I/O terminals during process.

### BACKGROUND OF THE INVENTION

An advanced packaging technology is called “wafer-level chip scale package” (WLCSP). Chip scale package refers to a technique to package a chip less than or equal to 1.5 times of the size of a chip with the advantage of smaller package footprint. The wafer-level chip scale package refers to a technique to assemble and test the wafer before singulation and thus reduces the packaging cost. Furthermore, while applying the technique of circuit redistribution on a wafer, pads at the center or perimeters of a die region could be arranged in array to acquire smaller contact area and higher I/O density while surface-mounting. In U.S. Pat. No. 6,228,687 entitled “WAFER-LEVEL PACKAGE AND METHORDS OF FABRICATING”, a method for fabricating wafer-level chip scale package is disclosed. A semiconductor wafer having chips is provided, and each chip has a plurality of pads forming on its active surface. The active surface is covered by a passivation layer, such as polyimide, by means of spin coating or spraying. A plurality of vias are formed through the passivation layer by etching or laser-drilling, which are corresponding in position to the pads. Thereafter, conductive materials are formed inside the vias by deposition or sputtering. On upper surface of the passivation layer, a conductive metal layer is formed, and then, it is etched to form a plurality of circuits which one end of the conductive metal layer is electrically connected to the pads of a die. A plurality of conductive bumps such as solder bumps are formed on the other end of the conductive metal layer and the bumps are reflowed. Therefore, the semiconductor device has a circuit redistribution structure. The conductive metal layer provides electrical connection from the pads at the edges of active surface to the bumps which are arranged in an array. While the surface of wafer-level chip scale package structure mounting to a printed circuit board, the interface produces thermal stress on solder bumps which was caused by the different coefficients of thermal expansion between the chip and the printed circuit board. The solder bumps do not have enough elasticity to absorb the thermal stress effectively and thus will be damaged and caused devices to fail.

### SUMMARY OF THE INVENTION

A main purpose of the present invention is to supply a method for fabricating wafer-level chip scale packages. A plurality of protruded sacrificial photoresists with supporting surfaces are formed on a surface of a wafer, then, a negative photoresist layer covers the protruded sacrificial photoresists. Patterning the negative photoresist layer in order to form a plurality of supporting bars on supporting surfaces of the sacrificial photoresists. Thereafter, a plurality of metal bars are formed on the supporting bars and connected to pads of the wafer, and then the sacrificial photoresists is removed in order to form a plurality of electrical pin terminals for the wafer-level chip scale packages which can be elastically surface-mounted to substrate or printed circuit board.

According to the present invention, the method for fabricating wafer-level chip scale packages includes a plurality of processes treated on a wafer. Firstly, to provide a wafer comprises a plurality of chips. The wafer has a surface forming with a plurality of pads. Then, on the surface of wafer forms a plurality of sacrificial photoresists which do not cover the pads but corresponding in position to the pads. Each of the sacrificial photoresists has a supporting surface. Thereafter, a negative photoresist layer is formed on the surface of wafer and cover the supporting surfaces of the sacrificial photoresists. The thickness of negative photoresist layer on the supporting surfaces is between 25 μm and 250 μm. Then, patterning the negative photoresist layer in order to form a plurality of supporting bars on supporting surface of the sacrificial photoresists. Thereafter, forming a plurality of metal bars on the corresponding supporting bars and connected to the pads. Then, the sacrificial photoresists are removed so that the supporting bars support the metal bars to assemble a plurality of electrical pin terminals of wafer-level chip scale packages which can be elastically surface-mounted to substrate or printed circuit board.

### DESCRIPTION OF THE DRAWINGS

FIG. 1 is a cross-sectional view of a wafer in accordance with the present invention;

FIG. 2 is a cross-sectional view of the wafer forming with sacrificial photoresists in accordance with the present invention;

FIG. 3 is a cross-sectional view of the wafer forming with a negative photoresist layer in accordance with the present invention;

FIG. 4 is a cross-sectional view of the wafer forming with supporting bars in accordance with the present invention;

FIG. 5 is a cross-sectional view of the wafer forming with metal bars in accordance with the present invention;

FIG. 6 is a cross-sectional view of the wafer after removing sacrificial photoresists to assemble elastically supporting electrical pin terminals in accordance with the present invention; and

FIG. 7 is a cross-sectional view of a fabricated wafer-level chip scale package in accordance with the present invention.

### DETAIL DESCRIPTION OF THE INVENTION

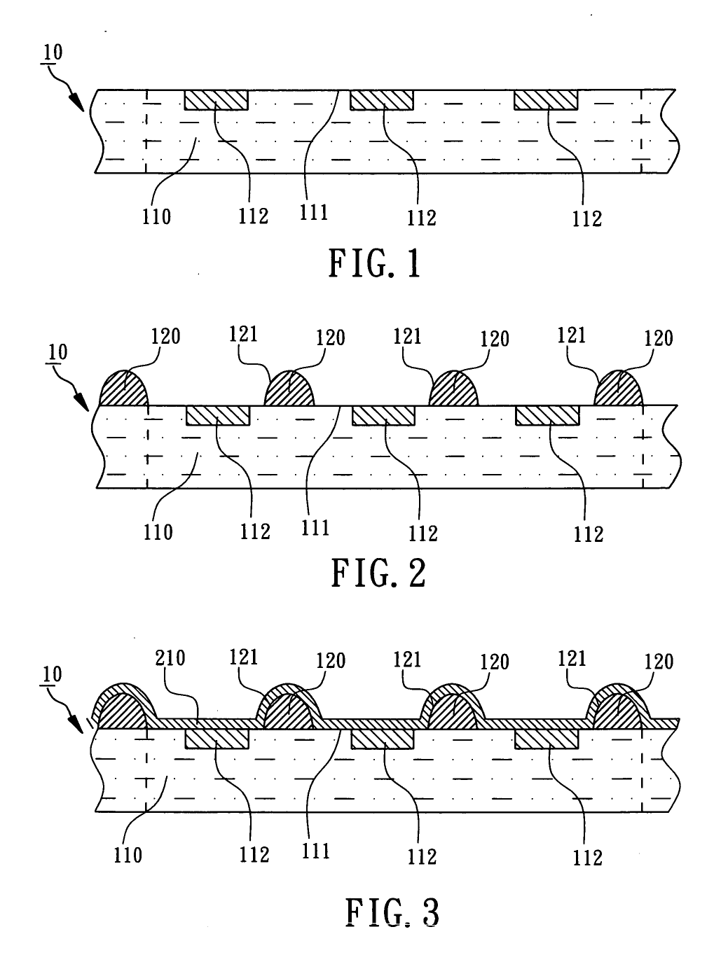

Please refer to the drawings attached, the present invention will be described by means of an embodiment below. Firstly, as shown in FIG. 1, a wafer 10 is provided. In this embodiment, the wafer 10 may includes memory chips, micro-processors or micro-controllers. It comprises a plurality of chips 110 integratedly and has a surface 111 for IC forming. The surface 111 of wafer 10 is formed with a plurality of pads 112, such as Al pad or Cu pad. The pads 112 could be redistributed upon the surface 111 of wafer 10 by the connection of redistribution circuits covered by a passivation layer (not shown in figure). The pads 112 are arranged in an array or in center or in perimeters on each chip region of a wafer. It is preferable that a metal adhesion layer (not shown in figure), such as nickel, gold, or copper, is formed on the pads 112.

Secondly, as shown in FIG. 2, a plurality of sacrificial photoresists 120 are formed on the surface 111 of wafer 10 by printing or dry film attaching & photolithography. The sacrificial photoresists are patterned from a positive photoresist solution or positive dry film. The sacrificial photoresists may be in shape of strip or bump. Each sacrificial photoresist 120 has a supporting surface 121. The sacrificial photoresists do not cover the pads 112 of chips 110, but corresponding in position to the pads 112. It is preferable that the supporting surfaces 121 are inclined from the surface 111 of chip 110 in order to facilitate the formation of pin terminals 20 (as shown in FIG. 5), and to acquire a better elasticity.

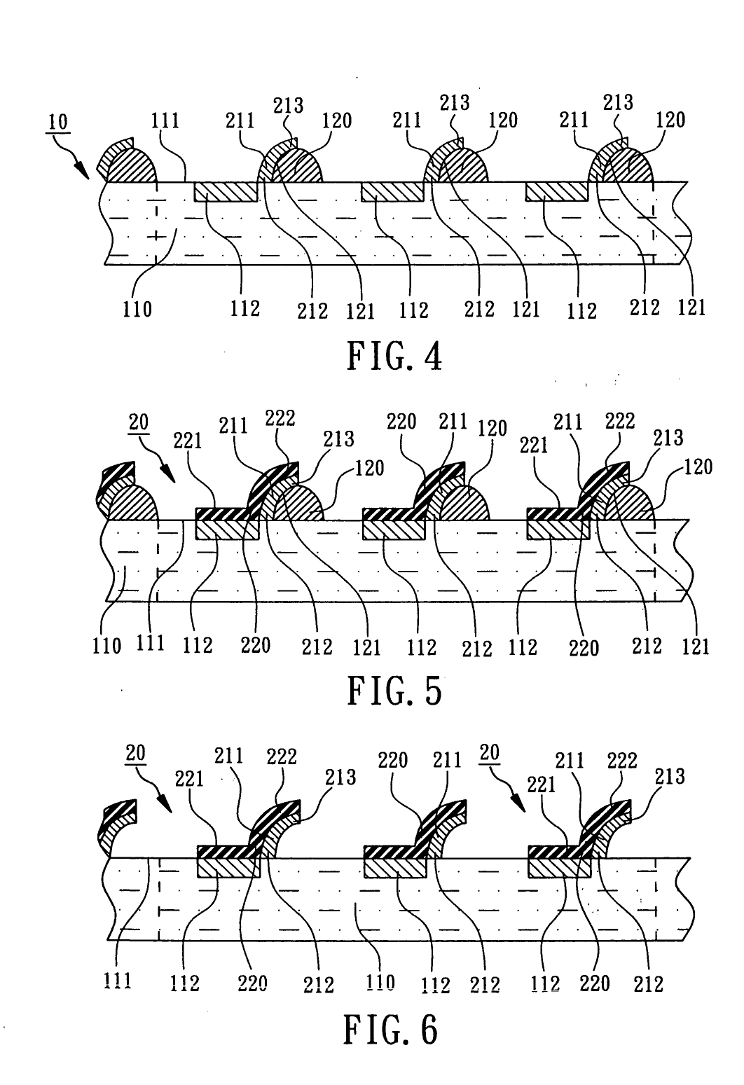

Thirdly, the process of forming a plurality of pin terminals enables to divide several detailed steps as shown in FIG. 3 to FIG. 6. As shown in FIG. 3, a negative photoresist layer 210 is formed by printing or spin coating on the surface of 111 of wafer 10 and covers the sacrificial photoresists 120. In this embodiment, the material of negative photoresist layer 210 is a product of MicroChem Company, with series No. SU-8 2000. The thickness of negative photoresist layer 210 on the supporting surfaces 121 is between 25 μm and 250 μm. The negative photoresist layer contains low dielectric constant (2.0˜3.0) polymer such as PI, BCB, and other photo sensitive materials. Fourthly, the negative photoresist layer 210 is patterned by photolithography, as shown in FIG. 4. A plurality of dielectric supporting bars 211 are formed from the patterned negative photoresist layer 210, each has a first end 212 and a second end 213. The dielectric supporting bars 211 are covered on the corresponding supporting surfaces 121 of sacrificial photoresists 120. Preferably, the first ends 212 of supporting bars 211 do not cover the pads 112 but adhere to the passivation layer of wafer 10 on the surface 111 of wafer 10 without pads 112.

Fifthly, as shown in FIG. 5, in order to form a plurality of metal bars 220, a metal layer is formed on the surface 111 of the wafer 110 by plating, evaporation or sputtering. Then the metal bars 220 are formed on the dielectric supporting bars 211 by etching the metal layer. Each metal bar 220 has a first end 221 and a second end 222. The metal bars 220 are made from the metal selected from the group of nickel, gold, copper, palladium and others. The first ends 221 of metal bars 220 are connected to the pads 112 of wafer 10. The metal bars 220 are bonded on the supporting bars 210 with slanted surface. Finally, the sacrificial phtoresists 120 is removed so that the second ends 213 of supporting bars 211 and the second ends 222 of metal bars 220 are suspended in the air. The metal bars 220 are supported by the supporting bars 211 to assemble elastic pin terminals 20, as shown in FIG. 6.

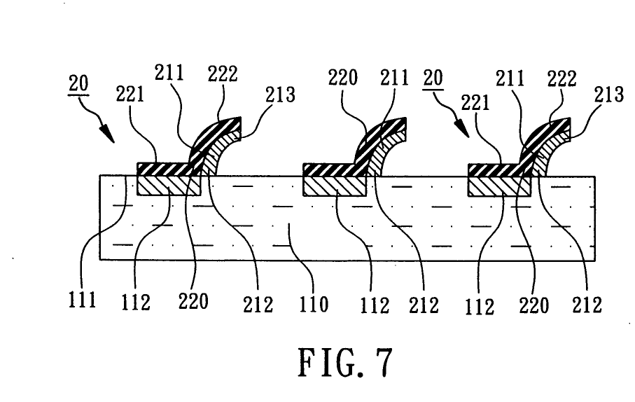

Furthermore, as shown in FIG. 7, after packaging and testing, the wafer 10 is singulated as separated wafer-level chip scale packages. According to the present invention the wafer-level chip scale package comprises the pin terminals 20 as I/O terminals.

Each pin terminal 20 has a metal bar 220 and a supporting bars 211 bonded under the metal bars to acquire a better elastic support. The pin terminals 20 have better elasticity. When the wafer-level chip scale package is surface-mounted to a printed circuit board by connecting the pin terminals 20, the pin terminals 20 are to provide elastic connections to effectively absorb the thermal stress created by the different coefficients of thermal expansion. It is to prevent any electrical failure between chip 10 and printed circuit boards.

The above description of embodiments of this invention is intended to be illustrative and not limiting. Other embodiments of this invention will be obvious to those skilled in the art in view of the above disclosure.

1. A method for fabricating wafer-level chip scale packages, comprising:
providing a wafer containing a plurality of chips, the wafer having a surface forming with a plurality of pads;
forming a plurality of sacrificial photoresists on the surface of the wafer, each sacrificial photoresist having a supporting surface without covering the pads;
forming a negative photoresist layer on the surface of the wafer, the negative photoresist layer covering the sacrificial photoresists;
patterning the negative photoresist layer to form a plurality of dielectric supporting bars, the dielectric supporting bars being formed on the supporting surfaces of sacrificial photoresists;
forming a plurality of metal bars on the dielectric supporting bars, the metal bars being bonded on the dielectric supporting bars and connecting to the pads to assemble a plurality of pin terminals; and
removing the sacrificial photoresists.

2. The method for fabricating wafer-level chip scale packages according to claim 1, wherein the negative photoresist layer on the supporting surfaces of the sacrificial photoresists has a thickness between 25 μm and 250 μm.

3. The method for fabricating wafer-level chip scale packages according to claim 1, wherein the supporting surfaces of the sacrificial photoresists are slanted from the surface of the wafer.

4. The method for fabricating wafer-level chip scale packages according to claim 1, wherein the sacrificial photoresists are made from the material selected from a positive photoresist and a positive dry film.

5. The method for fabricating wafer-level chip scale packages according to claim 1, wherein the negative photoresist layer is formed by printing or spin coating.

6. The method for fabricating wafer-level chip scale packages according to claim 1, wherein the metal bars are formed by plating, evaporation or sputtering.

7. The method for fabricating wafer-level chip scale packages according to claim 1, further comprising a step of singulating the wafer to form wafer-level chip scale packages including the chips after removing the sacrificial photoresist.
